(19) United States
(12) Patent Application Publication
(10) Pub. No.: US 2026/0198359 A1
(43) Pub. Date: Jul. 9, 2026

(54) DEVICE FOR HOLDING A SUBSTRATE AND A METHOD AND APPARATUS FOR FORMING AN ELECTRONIC MODULE

(71) Applicant: JCET STATS ChipPAC Korea Limited, Incheon (KR)

(72) Inventors: YeoJun YUN, Incheon (KR); MinSung LEE, Incheon (KR); HeeSoo LEE, Incheon (KR)

(21) Appl. No.: 19/443,041

(22) Filed: Jan. 8, 2026

(30) Foreign Application Priority Data
Jan. 9, 2025 (CN) 202510033892.3

(51) Int. Cl. H10W 72/00

(52) U.S. Cl. CPC H10W 72/07188; H10W 72/07141; H10W 72/07178; H10W 72/07227; H10W 72/07235; H10W 72/07236

(57) ABSTRACT

A device for holding a substrate is provided. The device comprises: a lower jig comprising a jig base, wherein a substrate has at least one electronic component mounted thereon via a solder paste, and the jig base is transparent to laser radiation; and an upper jig operably mounted on the lower jig, and defining together with the lower jig a cavity for accommodating the substrate, wherein the upper jig comprises a frame and a rib forming a grid pattern which defines a plurality of openings for exposing the at least one electronic component from the upper jig, and wherein when the upper jig is mounted on the lower jig to accommodate the substrate inside the cavity and the solder paste is reflowed by the laser radiation, the grid pattern is in contact with the substrate to apply a force to press the substrate against the lower jig.

### TECHNICAL FIELD

The present application generally relates to semiconductor technologies, and more particularly, to a device for holding a substrate, a method for forming an electronic module and an apparatus for forming the same with improved warpage control.

### BACKGROUND OF THE INVENTION

When semiconductor dice are packaged into a semiconductor package, they may be attached and bonded onto a package substrate via solder bumps or similar structures. A reflowing process may be desired to melt the solder bumps that interconnect the semiconductor dice with the package substrate. However, as heat is applied to the package substrate during the reflowing process, the package substrate may warp and thus bulge from a carrier where it is placed. The warpage of the package substrate may cause irregular joints and bump cracks, thereby leading to a low yield.

Jigs may be used to resolve the warpage of package substrates. For example, a lower jig and an upper jig may sandwich the package substrate therebetween, to press the package substrate especially at positions potentially with large warpages. However, the conventional jigs cannot satisfactorily reduce severe warpage, especially for thinner package substrates. Moreover, the conventional jigs may not be applicable in some advanced reflowing processes to reflow the solder bumps, such as a laser assisted bonding or reflowing process.

Therefore, a need exists for a device for holding a substrate and a method for forming an electronic module with improved warpage control.

### SUMMARY OF THE INVENTION

An objective of the present application is to provide a device for holding a substrate and a method for forming an electronic module with improved warpage control.

According to an aspect of the present application, a device for holding a package substrate is disclosed. The device comprises: a lower jig comprising a jig base for placing a substrate, wherein the substrate has at least one electronic component each being mounted thereon via a solder paste, and the jig base is transparent to laser radiation; and an upper jig operably mounted on the lower jig, and defining together with the lower jig a cavity for accommodating the substrate, wherein the upper jig comprises a frame and a rib inside the frame, and the frame and the rib form a grid pattern defining a plurality of openings for exposing the at least one electronic component from the upper jig, and wherein when the upper jig is mounted on the lower jig to accommodate the substrate inside the cavity and the solder paste is reflowed by the laser radiation, the grid pattern is in contact with the substrate to apply a force to press the substrate against the lower jig.

According to another aspect of the present application, a method for forming an electronic module is disclosed. The method comprises: placing a substrate between a lower jig and an upper jig, wherein the lower jig comprises a jig base transparent to laser radiation and for holding the substrate, and the upper jig comprises a frame and a rib inside the frame to form a grid pattern which defines a plurality of openings exposing a portion of the substrate; passing at least one electronic component through the at least one of the plurality of openings, respectively, to mount each of the at least one electronic component on the substrate via a solder paste; and reflowing the solder paste by applying laser radiation to the substrate through the jig base to form the electronic module, wherein the grid pattern is in contact with the substrate to apply a force to press the substrate against the lower jig when the solder paste is being reflowed.

According to another aspect of the present application, an apparatus for forming an electronic module. The apparatus comprises: a platform configured for placing a lower jig and an upper jig which define therebetween a cavity for accommodating a substrate having at least one electronic component mounted thereon via a solder paste, wherein the lower jig comprises a jig base which is transparent to laser radiation and for holding the substrate, and the upper jig comprises a frame and a rib inside the frame to form a grid pattern which defines a plurality of openings for exposing the at least one electronic component when the substrate is accommodated in the cavity; and a laser source configured for applying laser radiation to the substrate through the jig base to reflow the solder paste, wherein the grid pattern is in contact with the substrate to apply a force to press the substrate against the lower jig when the solder paste is being reflowed.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1D illustrate a device for holding a substrate according to a first embodiment of the present application.

FIG. 2 illustrates a device for holding a substrate according to a second embodiment of the present application.

FIGS. 3A to 3D illustrate various steps of a method for forming an electronic module according to a third embodiment of the present application.

FIG. 4 illustrates a reflowing process in a method for forming an electronic module according to a fourth embodiment of the present application.

FIG. 5 illustrates an apparatus for forming an electronic module according to a fifth embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, a reflowing process may be implemented to melt solder bumps that interconnect semiconductor dice with a substrate. During the reflowing process, a lower jig and an upper jig may sandwich the substrate therebetween to press the substrate especially at positions potentially with large warpages. However, the conventional jigs cannot satisfactorily reduce severe warpage. In particular, in a laser assisted bonding or reflowing process, solder bumps are reflowed by laser radiation emitted from a laser source below the substrate. The conventional jigs may not be applicable for this reflowing process with reverse laser radiation.

To address this issue, a device for holding a substrate is provided, which may be used in packaging processes such as a solder reflowing process. The device includes a lower jig having a jig base which is transparent to laser radiation, and an upper jig operably mounted on the lower jig. The substrate is accommodated between the lower jig and the upper jig, and has at least one electronic component each of which can be mounted on the substrate via a solder paste. The upper jig includes a grid pattern defining a plurality of openings, which are used for exposing the at least one electronic component from the upper jig. During a reflowing process of the solder paste, laser radiation passes through the jig base and reaches the substrate to reflow the solder paste. Meanwhile, the grid pattern is in contact with the substrate to apply a force to press the substrate against the lower jig. To be more specific, the grid pattern may press the substrate at its peripheral region and its central region. As such, a larger area of the substrate may be pressed against the lower jig, which alleviates the warpage of the substrate with a greater force and in a more uniform manner.

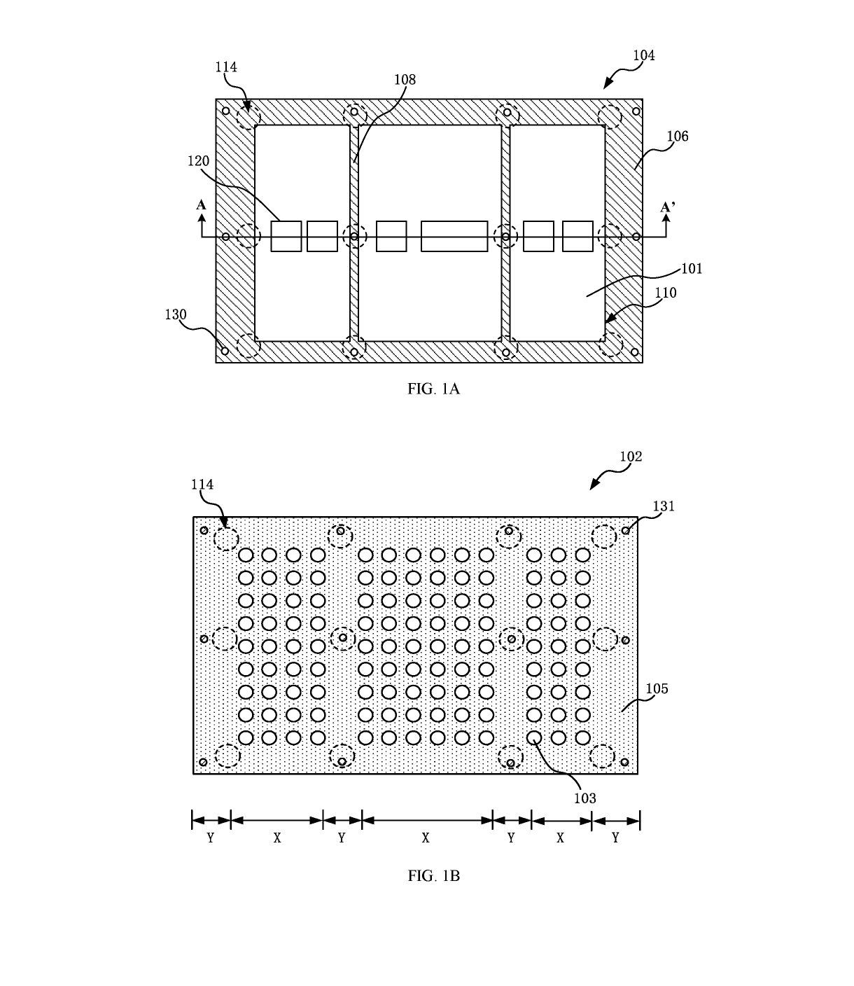

FIGS. 1A to 1D illustrate a device for holding a substrate according to a first embodiment of the present application. FIG. 1A is a top view of the device, and FIG. 1B is a bottom view of the device. FIG. 1C is a cross sectional view of the device along line AA’ in FIG. 1A, and FIG. 1D shows an enlarged view of a zone V in FIG. 1C.

As shown in FIGS. 1A to 1C, a device for holding a substrate 101 is provided. In particular, the device includes a lower jig 102 and an upper jig 104 to accommodate the substrate 101 therebetween. The substrate 101 has at least one electronic component 120, and each of the at least one electronic component 120 is mounted on the substrate 101 via a solder paste. The device is used for holding the substrate 101 during a reflowing process of the solder paste, such that the solder paste is melted to interconnect the at least one electronic component 120 with the substrate 101.

In some embodiments, the substrate 101 may be attached with various electronic components 120. The electronic components 120 may be attached on a top surface of the substrate 101 in different regions, as shown in FIGS. 1A and 1C. The electronic components 120 may include any of a variety of types of semiconductor dice, semiconductor packages, or discrete devices. For example, the electronic components 120 may include one or more digital chips, analog chips or mixed signal chips, such as application-specific integrated circuit (“ASIC”) chips, sensor chips, wireless and radio frequency (RF) chips, memory chips, logic chips or voltage regulator chips. The electronic components 120 may also include one or more passive electrical components such as resistors, capacitors, inductors, etc. In some embodiments, the electronic components 120 may include an integrated circuit chip for wireless communication and/or signal processing, which may require antennas for transmitting and receiving wireless signals. In some embodiments, the electronic components 120 may further include output and/or input circuits for an antenna structure for wireless communication.

The electronic components 120 may be attached on the substrate 101 in a specific layout, depending on the sizes of the electronic components 120 and the substrate 101. For example, in the embodiment shown in FIG. 1C, the electronic components 120 may have different sizes and heights. Also, the electronic components 120 may be classified into several subgroups. Each of the subgroups may occupy a respective portion of the substrate 101, and a portion of the substrate 101 between two adjacent subgroups may be exposed for mounting of the upper jig 104. The portions of the substrate 101 disposed with the subgroups of the electronic components 120 may be referred to as active regions, while the exposed portions of the substrate 101 may be referred to as non-active region(s). It can be appreciated that due to the mechanical and material properties of the electronic components 120 and the substrate 101, it is applicable to apply a force to the non-active region, rather than to the active region of the substrate 101. Furthermore, the numbers of the electronic components 120 included in the subgroups may be the same or different. Also, the sizes, heights, structures and layouts of the electronic components 120 in the subgroups may be the same or different. In some embodiments, various subgroups of electronic components 120 may be attached on the substrate 101 approximately in a straight line. In some other embodiments, the subgroups of electronic components may be placed on the substrate 101 in a staggered layout, for example, near different corners or edges of the substrate 101.

As mentioned above, the electronic components 120 may be attached onto the substrate 101 via respective solder pastes, and thus a reflowing process or other similar heating or curing process may be desired to be performed to the substrate 101 when the substrate 101 is held by the device. It can be appreciated that the substrate 101 may further include conductive patterns where the solder pastes may be deposited or applied. In some embodiments, the substrate 101 may include one or more dielectric layers, with conductive layers and vias (not shown) formed in the dielectric layers. For example, the dielectric layers may be laminated films that are laminated to each other. Due to the composite composition of the substrate 101 and the various electronic components 120 attached thereon, the substrate 101 may warp when heat is applied during a reflowing process, for example.

The upper jig 104 is operably mounted on the lower jig 102, such that the two jigs 102, 104 are operable to hold the substrate 101 therebetween. The lower jig 102 has a jig base 105 which is used for holding the substrate 101. For example, the lower jig 102 may be a plate on which the substrate 101 can lay flat. In some embodiments, the lower jig 102 may be slightly recessed in its central region, to receive the substrate 101 and prevent it from sliding off the lower jig 102, for example, when the lower jig 102 tilts a little. In some alternative embodiments, the lower jig 102 may have a flat top surface. Moreover, the jig base 105 may include a plurality of device placement regions X and an assembling region Y. When the substrate 101 is placed on the lower jig 102, each of the plurality of the device placement regions X is aligned with one of the active regions of the substrate 101, and the assembling region Y is aligned with the non-active region of the substrate 101.

Furthermore, as shown in FIGS. 1B and 1C, the jig base 105 of the lower jig 102 is formed of a material that is transparent to laser radiation. In some embodiments, the jig base 105 may include glass (e.g., soda lime glass) or quartz. During a reflowing process of the solder paste, laser radiation, for example, infrared radiation may be emitted from a laser source disposed below the jig base 105. The laser radiation may pass through the jig base 105 to reach the substrate 101, and then heat and reflow the solder paste. In some preferred embodiments, more than 90% of the laser energy entering the jig base 105 can be transmitted to the substrate 101 and be used for the reflowing process of the solder paste.

As shown in FIGS. 1A and 1B, the lower jig 102 may have a rectangular shaped layout. Accordingly, the upper jig 104 may have a shape and size substantially the same as the lower jig 102, such that the two jigs 102 and 104 can be aligned and attached with each other. In particular, the upper jig 104 may have a frame 106 in its peripheral region, and at least one rib 108 inside the frame 106 (i.e., in a central region of the upper jig 104). The frame 106 may have a shape of a rectangular ring including two parallel vertical portions, and two parallel and horizontal portions each connected with one of the two vertical portions. In the embodiment shown in FIGS. 1A to 1C, the upper jig 104 includes two ribs 108 that extend in parallel with each other between the two vertical portions of the frame 106. The two ribs 108 are separated from each other by a certain distance, and each of the two ribs 108 is parallel to the two vertical portions of the frame 106 and perpendicular to the two horizontal portions of the frame 106. Additionally, each of the ribs 108 traverses across an inner opening of the frame 106 and is connected with both of the horizontal portions of the frame 106. In this way, the frame 106 and the ribs 108 form a grid pattern defining a plurality of openings 110 within the upper jig 104. The openings 110 may be big enough to allow the electronic components 120 to be exposed through the grid pattern 108. In that case, no force may be applied to the electronic components 120 by the upper jig 104, thereby damages to the electronic components 120 can be avoided. In the embodiment shown in FIGS. 1A and 1B, the ribs 108 and the frame 106 define three openings 110 which expose three subgroups of electronic components 120 respectively. It can be appreciated that the grid pattern 108 may have more or fewer ribs 108, or may have other layouts. For example, only one rib 108 may be arranged in the center of the inner opening of the frame 106, such that the inner opening may be separated by the rib 108 into two identical or similar openings 110, which expose two subgroups of electronic components 120 respectively. In some alternative embodiments, another rib 108 may be formed in the grid pattern and above the exposed portion of the substrate 101 between two adjacent subgroups of electronic components 120, thereby providing a grid pattern with more openings 110. The rib(s) 108 in the grid pattern may produce and apply to the substrate 101 a greater and more uniform force, which is beneficial for the mitigation of warpages of the substrate 101, as will be elaborated later.

In some embodiments, the at least one rib 108 and the frame 106 may be formed as a single piece. In some other embodiments, each of the at least one rib 108 and the frame 106 may be provided separately and be assembled together before the reflowing process. In this case, a certain number of rib(s) 108 may be selected and placed at required positions of the frame 106 according to the layout of the electronic components 120 on the substrate 101. In some embodiments, the upper jig 104 may further include a fixing element, such as a fastener, for fixing the rib 108 at a required position of the frame 106. In some other embodiments, the horizontal portions of the frame 106 may include a pair of slots each formed on an inner surface of one of the horizontal portions, and two ends of the rib may be inserted into the pair of slots respectively to secure the rib 108 in place with the frame 106. In some cases, the number of the pair(s) of the slots is greater than the number of the rib(s) 108. In this way, the grid pattern may have various layouts with a single set of frame 106 and ribs 108 by simply changing the number of ribs 108 connected with the frame 106 and/or the position of the rib(s) 108 on the frame 106, thereby enhancing flexibility of using the upper jig 104. In some further embodiments, the ribs 108 and the frame 106 may be formed of a ferromagnetic material such as steel. The ribs 108 may be attracted by the frame 106 and be fixed in place when they are placed on the frame 106, which provides more convenience for an assembling process.

As shown in FIG. 1C, the upper jig 104 further includes a skirt portion 112 at a periphery of a bottom surface of the frame 106. When the upper jig 104 is mounted on the lower jig 102, the skirt portion 112 is in contact with the lower jig 102 such that a cavity is defined between the jig base 105 and the grid pattern to accommodate the substrate 101. The skirt portion 112 may have a thickness substantially equal to or slightly smaller than a thickness of the substrate 101 (not including the electronic components 120 mounted thereon). In the embodiment where the lower jig 102 may be recessed in its central region, a sum of the thickness of the skirt portion 112 and a depth of the recess of the lower jig 102 may be substantially equal to or slightly smaller than the thickness of the substrate 101. In this way, a clamping force may be applied to the substrate 101 at its periphery through the lower and upper jigs 102 and 104, without leading to any damages to the electronic components 120, and the substrate 101 can be secured in place between the lower and upper jigs 102 and 104.

In some embodiments, when the substrate 101 is inserted between the lower jig 102 and the upper jig 104, each of the ribs 108 of the grid pattern 108 may be in contact with the substrate 101 so as to apply a force onto the substrate 101 in its non-active region. Moreover, the jig base 105 includes the plurality of device placement regions X and the assembling region Y. When the upper jig 104 is mounted on the lower jig 102, each of the plurality of the device placement regions X is aligned with one of the openings 110, and the assembling region Y is aligned with the frame 106 or the rib 108 of the grid pattern. In some other cases, the substrate 101 may have a thickness slightly smaller than the gap between the lower and upper jigs 102 and 104, and the grid pattern 108 or particularly its ribs 108 may not be in contact with the top surface of the substate 101 before the reflowing process of the solder paste. However, when the solder paste is reflowed by the laser radiation, the grid pattern may be in contact with the substrate 101 to apply a force to press the substrate 101 against the lower jig 102.

Furthermore, as shown in FIGS. 1B and 1C, one or more magnets 114 may be embedded within the jig base 105. In addition, the grid pattern is at least partially formed of a ferromagnetic material. As such, the grid pattern of the upper jig 104 is attracted by the plurality of magnets 114 when the upper jig 104 is mounted on the lower jig 102. Due to the magnetic attraction force between the grid pattern and the magnets 114, the grid pattern may get closer to the jig base 105, thereby increasing the force applied to the substrate 101 through the ribs 108 and the frame 106 of the grid pattern. FIG. 1D shows an enlarged view of a zone V in FIG. 1C, which illustrates the force applied to the substrate 101 through the ribs 108 and frame 106, to overcome the bulging of the substrate 101. To be more specific, the frame 106 of the grid pattern may press a peripheral region of the substrate 101, and the ribs 108 of the grid pattern may press an exposed portion of a central region of the substrate 101. In this way, the force may be applied to a larger area of the substrate 101 and also be applied in a more uniform and controlled manner, so as to reduce warpage of the substrate 101 when the solder paste is being reflowed. It should be noted that the rib 108, the substrate 101 and the magnet 114 are illustrated in FIG. 1D, and other components in the zone V of FIG. 1C are omitted for simplicity.

In the embodiment shown in FIGS. 1A and 1B, the magnets 114 include two columns of magnets 114 aligned with two vertical portions of the frame 106 respectively, and another two columns of magnets 114 aligned with the respective two ribs 108 of grid pattern. In some embodiments, each column of magnets 114 include three magnets 114 which are uniformly distributed across the respective vertical portion of the frame 106 or the respective rib 108, as shown in FIG. 1B. In some other embodiments, the magnets 114 may not be uniformly distributed, and more magnets 114 may concentrate in a portion of the assembling region Y which is closer to the electronic components 120, so as to apply a greater force to a portion of the substrate 101 where more severe warpage may occur. It can be appreciated that more or fewer magnets 114 may be embedded in the jig base 105, depending on the layout of the grid pattern. In some examples, each magnet 114 may have a circular shape, or be of a rectangular, square or any other suitable shape. A distance from each magnet 114 to a top surface of the lower jig 102 may be 0.2 mm to 20 mm, for example, to allow for a proper magnetic interaction between the magnets 114 and the upper jig 104. In some embodiments, the magnets 114 may be permanent magnets, while in some alternative embodiments, the magnets 114 may be electromagnets which can be activated or disactivated by a control circuit. In addition, in the embodiments where the magnets 114 may be electromagnets, a strength of the magnetic field produced by the magnets 114 may be adjustable by the control circuit, for example, through adjustment of a level of power supply to the electromagnets. In this way, the strength of the magnetic field may be adjusted less to mitigate smaller warpages, or greater to mitigate bigger warpages. Optionally, a warpage detection apparatus may be used to detect the warpages of the substrate 101 at different positions to adjust the magnetic field.

Although it is shown in FIG. 1A that the magnets 114 may be disposed below both the frame 106 and the ribs 108, in some alternative embodiments, the magnets 114 may be disposed only below the ribs 108. In that case, other fasteners such as clamps, pins or clips may be arranged at or around the frame 106 of the lower jig 102 to secure the lower jig 102 with an upper jig 104 and maintain a substrate 101 therebetween.

In some other embodiments, a portion of the upper jig 104, rather than an entirety of the upper jig 104, may be formed of a ferromagnetic material. For example, the upper jig 104 may have a base material which can be a dielectric material such as rubber or plastics, or a metal such as copper, and a bottom material which can be a ferromagnetic material attached to the base material and closer to the lower jig 102 when the upper jig 104 is placed on the lower jig 102. In some preferred embodiments, a coating layer of silicone or other similar elastomeric material may be disposed under the bottom material to buffer between the substrate 101 on the lower jig 102 and the upper jig 104. In some alternative embodiments, the upper jig 104 may also include one or more magnets 114 that may be embedded within the grid pattern, especially within the ribs 108 and/or the frame 106. These magnets 114 may further improve the magnetic interaction with the magnets 114 in the lower jig 102.

Moreover, as shown in FIGS. 1B and 1C, the lower jig 102 further includes a plurality of passages 103 extending through the jig base 105. The passages 103 are fluidly coupled to a vacuum source, so as to apply a vacuum pressure to the substrate 101 when the substrate 101 is placed on the lower jig 102. In some examples, each passage 103 may have a circular shape, or be of a rectangular, square or any other suitable shape. In some embodiments, the passages 103 may be interconnected with each other via additional channels within the jig base 105. A vacuum attraction force applied onto the substrate 101 which is generated by the vacuum pressure may further reduce the warpage of the substrate 101 during the reflowing process. In some preferred embodiments, the plurality of passages 103 are uniformly distributed within the plurality of device placement regions X of the jig base 105, so as to apply the vacuum attraction force to the active regions of the substrate 101. In this way, the warpage of the active regions of the substrate 101 may be reduced due to the vacuum attraction force applied to the active regions through the passages 103, and the warpage of the non-active region of the substrate 101 may also be reduced due to the magnetic attraction force applied to the non-active region by the magnetic attraction between the grid pattern and the magnets 114. As such, a larger area of the substrate 101 may be pressed against the lower jig 102, which further alleviates the warpage of almost an entirety of the substrate 101 in a more sufficient and uniform manner.

In addition, the lower jig 102 further includes a plurality of fixing pins 131 protruding from its top surface. In some embodiments, the fixing pins 131 may extend from an interior to an exterior of the jig base 105. The fixing pins 131 may be distributed within the assembling region Y of the jig base 105, for example, at a periphery of the jig base 105 and within a central region of the jig base 105, as shown in FIG. 1C. In some embodiments, the fixing pins 131 may be close to the magnets 114. It can also be appreciated that the fixing pins 131 may penetrate through the embedded magnets 114. Accordingly, the grid pattern further includes a plurality of through holes 130, for example, extending through the frame 106 and the ribs 108. When the upper jig 104 is mounted on the lower jig 102 to accommodate the substrate 101, the plurality of fixing pins 131 are received within the through holes 130 respectively. As such, the upper jig 104 can be fixed in place with the lower jig 102 without undesired lateral movement to secure the substrate 101 therebetween.

In some other embodiments, fasteners such as clamps, pins or clips may be arranged at the frame 106 of the upper jig 104 to secure the upper jig 104 with the lower jig 102 and maintain a substrate 101 therebetween. In some alternative embodiments, the jig base 105 may include passages 103 within both of the device placement regions X and the assembling region Y, so as to apply the vacuum pressure to the entirety of the substrate 101. Therefore, at least some of the fixing pins 131 may be omitted.

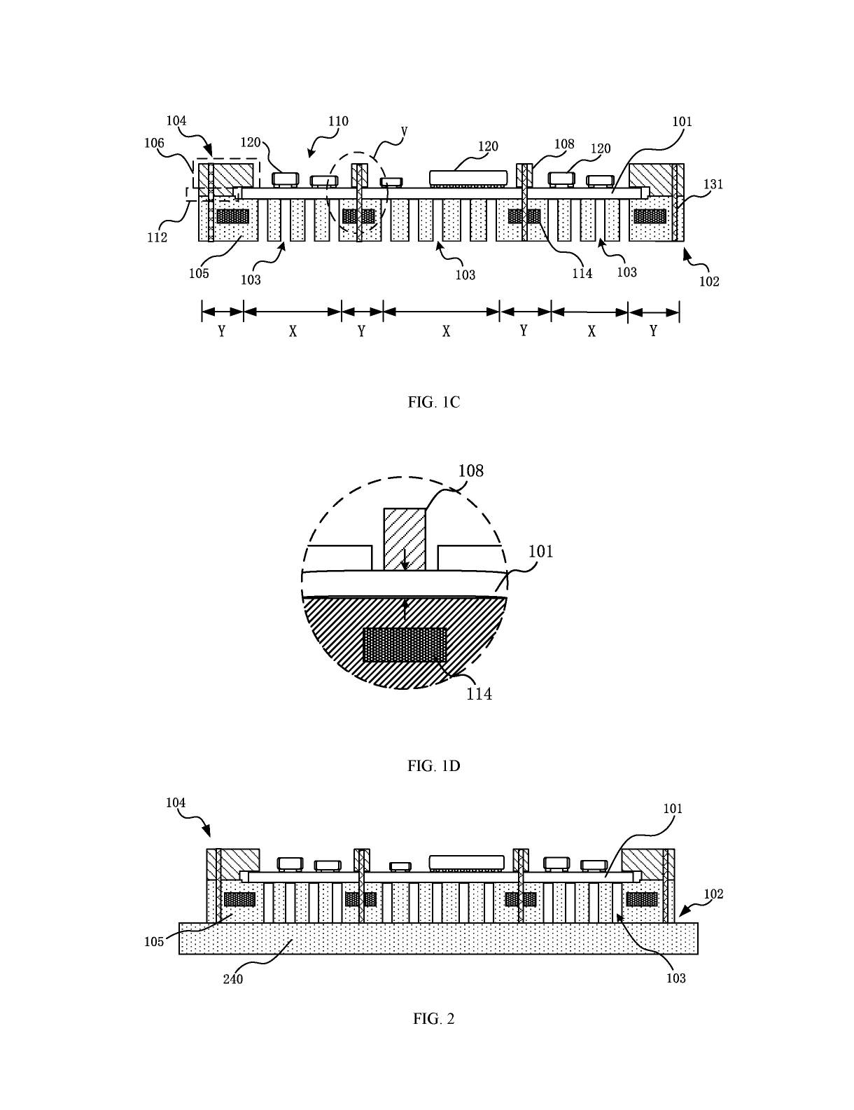

FIG. 2 illustrates a device for holding a substrate 101 according to a second embodiment of the present application. The device shown in FIG. 2 has the same structure and materials as the device shown in FIGS. 1A to 1D, except that the device in FIG. 2 further includes a heating block 240 placed below a lower jig 102.

As shown in FIG. 2, the heating block 240 may be in direct contact with a bottom surface of the lower jig 102. When the solder paste is heated and reflowed by the laser radiation, the heating block 240 may apply additional heat to the lower jig 102. In addition, the heating block 240 is transparent to laser radiation, such that the laser radiation can successfully pass through the heating block 240 and the lower jig 102 and reach a substrate 101 and a solder paste thereon. The heating block 240 may include a material which is the same as that of the lower jig 102, for example, quartz or glass. In this way, apart from the laser radiation energy applied to the solder paste, the additional thermal energy may raise the ambient temperature of an atmosphere surrounding the substrate 101 during the laser radiation process to alleviate heat dissipation. Also, since the heating block 240 is in direct contact with the lower jig 102, the additional thermal energy can be convectively transferred to the lower jig 102 and thus to the substrate 101 and the solder paste. This enables the solder paste to be heated through a hybrid heating mechanism which incorporates both of the laser radiation heating and the convection heating, thereby achieving a higher reflowing efficiency and a lower energy demand from the laser source. Moreover, with a lower laser radiation energy applied from the laser source, an overall heat generated within the formed device may be reduced, which may prevent or alleviate a burning effect caused by the excessive laser radiation energy. In some embodiments, the heating block 240 may include a heater for generating the additional thermal energy. In some other embodiments, the heating block 240 may be preheated to a high temperature to transfer the thermal energy to the lower jig 102. In addition, the heating block 240 may include channels which connect the passages 103 of the lower jig 102 and the vacuum source, such that the vacuum pressure can be applied to the substrate 101 through the channels of the heating block 240 and the passages 103 of the lower jig 102.

In some embodiments, the heating block 240 may have a base portion and a sidewall surrounding the base portion. Therefore, the sidewall defines a cavity above the base portion to accommodate the lower jig 102, and a top surface of the base portion and an inner surface of the sidewall are attached to the bottom surface and the lateral surface of the lower jig 102 respectively. In this way, the thermal energy generated by the heating block 240 may be transferred to the lower jig 102 through a larger contact area between the heating block 240 and the lower jig 102, thereby improving the heating efficiency. In addition, the channels of the heating block 240 may pass through the base portion to connect the passages 103 to the vacuum source. It can be appreciated that the channels may also pass through the sidewall, which shorten the distance from the passages 103 of the lower jig 102 to the vacuum source.

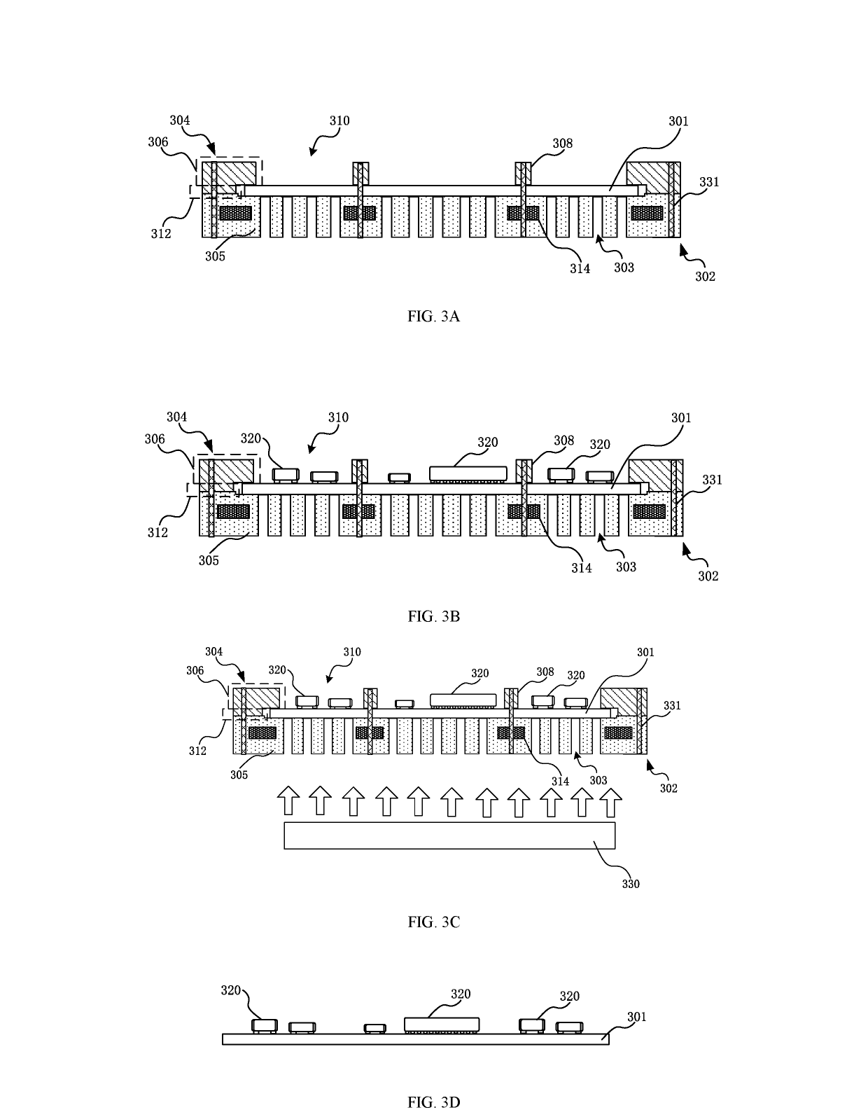

FIGS. 3A to 3D illustrate various steps of a method for forming an electronic module according to a third embodiment of the present application. A least a portion of the steps of the method may be implemented by the device shown in FIGS. 1A to 1C.

As shown in FIG. 3A, a device for holding a substrate 301 is provided. The device includes a lower jig 302 and an upper jig 304. To be more specific, the lower jig 302 includes a jig base 305 transparent to laser radiation. The substrate 301 is placed on a top surface of the jig base 305. The upper jig 304 includes a frame 306 and at least one rib 308 inside the frame 306 to form a grid pattern. The upper jig 304 is mounted on a top surface of the lower jig 302 to accommodate the substrate 301 between the lower jig 302 and the upper jig 304. The grid pattern of the upper jig 304 defines a plurality of openings 310 exposing a portion of the substrate 301. Moreover, the frame 306 and each of the ribs 308 of the grid pattern may be in contact with the substrate 301. The rib(s) 308 in the grid pattern can produce a greater and more uniform force to the substrate 301, which is beneficial for the mitigation of potential warpages of the substrate 301 that may be generated during a reflowing process or another similar heating process.

In some embodiments, the upper jig 304 further includes a skirt portion 312 at a periphery of a bottom surface of the frame 306. When the upper jig 304 is mounted on the lower jig 302, the skirt portion 312 is in contact with the lower jig 302. A clamping force may be applied to the substrate 301 at its periphery through the lower and upper jigs 302 and 304. Furthermore, one or more magnets 314 may be embedded within the jig base 305. In addition, the grid pattern is at least partially formed of a ferromagnetic material. In addition, the lower jig 302 further includes a plurality of fixing pins 331 protruding from its top surface. Accordingly, the grid pattern further includes a plurality of through holes, for example, through the frame 306 and the ribs 308. When the upper jig 304 is mounted on the lower jig 302 to accommodate the substrate 301, the plurality of fixing pins 331 are inserted into the through holes 330 respectively. Moreover, the lower jig 302 further includes a plurality of passages 303 extending through the jig base 305, which are fluidly coupled to a vacuum source to apply a vacuum pressure to the substrate 301.

Next, as shown in FIG. 3B, at least one electronic component 320, each of which may be dispensed with a solder paste on its bottom surface, may pass through the at least one of the plurality of openings 310, respectively. In this way, each of the at least one electronic component 320 is mounted on the substrate 301 via the solder paste. In some other embodiments, the solder paste may be applied onto the exposed portion of the substrate 301 before the at least one electronic component 320 is mounted on the substrate 301. In some embodiments, the solder paste may include a metal solder material such as tin and a flux material.

Next, as shown in FIG. 3C, laser radiation is emitted from a laser source 330 disposed below the lower jig 302. The laser radiation may pass through the jig base 305 to reach the substrate 301 and the solder paste. In this way, a sufficient amount of laser radiation energy may then be transferred to the substrate 301 and the solder paste, such that the solder paste can be heated and reflowed to form solder bumps. Therefore, an electronic module with reduced substrate warpage is formed. The laser radiation may provide more uniform and rapid heating to the solder paste during the reflowing process, which helps to form the electrical connection with a high quality. Also, since the laser radiation is applied to the substrate 301 from its bottom surface, it may avoid undesired influence to the electronic component(s) 320 during transmission of the laser radiation. During the reflowing process, a non-active region of the substrate 301, that is, an exposed portion of the substrate 301 which is not occupied by the at least one electronic component 320, is pressed against the lower jig 302 by the grid pattern. To be more specific, the frame 306 of the grid pattern may press a peripheral region of the substrate 301, and the ribs 308 of the grid pattern may press an exposed portion of a central region of the substrate 301. In addition, active regions of the substrate 301, that is, the other portions of the substrate 301 which are occupied by the at least one electronic component 320, may be attracted to the lower jig 302 due to a vacuum attraction force caused by the vacuum pressure applied through the passages 303 of the lower jig 302. In this way, a larger area of the substrate 301 may be pressed against the lower jig 302, which further alleviates the warpage of almost an entirety of the substrate 301 in a more sufficient and uniform manner.

In some preferred embodiments, the laser radiation may be applied for a duration ranging between 2 seconds to 5 seconds. In addition, a temperature of the lower jig 302 may be maintained within 80℃~100℃. As such, the temperature of the lower jig 302 may be raised and maintained at a relatively moderate level, which avoids a thermal shock of the solder paste resulted from a sudden temperature raise.

Next, after the electrical connection between the at least one electronic component 320 and the substrate 301 is formed, the laser source 330 may be turned off. Then the reflowing process of the solder paste is ended, and the formed electronic module may be cooled down. For example, the temperature of the substrate 301 and the solder paste may begin to decrease to a lower temperature such as the room temperature. In some preferred embodiments, the cooling step of the electronic module may last for 5 seconds or longer, thereby allowing for sufficient solidification of the solder paste, i.e., formation of the solid solder bump.

Next, a residual of the flux material may be removed from the electronic module by a cleaning process. Next, the upper jig 304 and the lower jig 302 may be separated from the electronic module, and the electronic module can proceed with a testing process or a subsequent fabrication process.

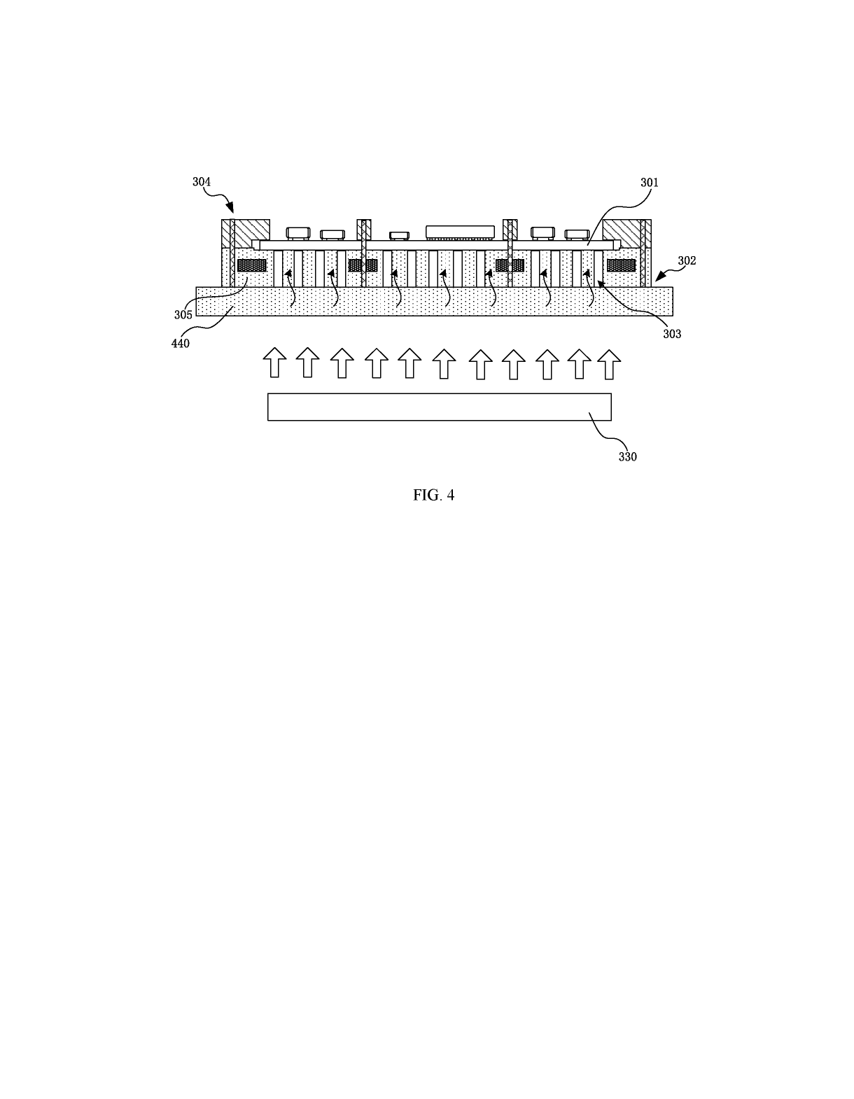

FIG. 4 illustrates a reflowing process in a method for forming an electronic module according to a fourth embodiment of the present application. The step illustrated in FIG. 4 may be implemented after the steps illustrated in FIGS. 3A and 3B have been performed, instead of the step illustrated in FIG. 3C. Therefore, details of the other steps may be referred to the embodiment described with reference to FIGS. 3A and 3B and will not be elaborated below.

As shown in FIG. 4, a heating block 440 is attached on the lower jig 302. The heating block 440 may be in direct contact with a bottom surface of the lower jig 302. When the solder paste is heated and reflowed by the laser radiation, the heating block 440 may apply additional heat to the lower jig 302. In addition, the heating block 440 is transparent to the laser radiation, such that the laser radiation can pass through the heating block 440 and the lower jig 302 and reach the substrate 301 and the solder paste. The heating block 440 may include a material which is the same as that of the lower jig 302, for example, quartz or glass. Since the heating block 440 is in direct contact with the lower jig 302, the additional thermal energy can be convectively transferred to the lower jig 302 and thus to the substrate 301 and the solder paste. This enables the solder paste to be heated through a hybrid heating mechanism which incorporates the direct laser radiation heating and the convection heat transferred from the heating block 440, thereby achieving a higher reflowing efficiency and a lower energy demand from the laser source 330. Details of the heating block 440 may be referred to the heating block 240 in the embodiment described with reference to FIG. 2 and will not be elaborated below.

In some embodiments, the heating block 440 may be placed onto the lower jig 302 before the reflowing process of the solder paste on the substrate 301 to preheat the lower jig 302. For example, the heating block 440 may be placed onto the lower jig 302 after the at least one electronic component 320 is mounted on the substrate 301 and before the solder paste is reflowed by the laser radiation. It can also be appreciated that the heating block 440 can be attached to the lower jig 302 during the reflowing process. In some other embodiments, the heating block 440 may be attached to the lower jig 302 before the substrate 301 is placed on the lower jig 302. In this case, the heating block 440 can be turned on shortly before or during the reflowing process of the solder paste.

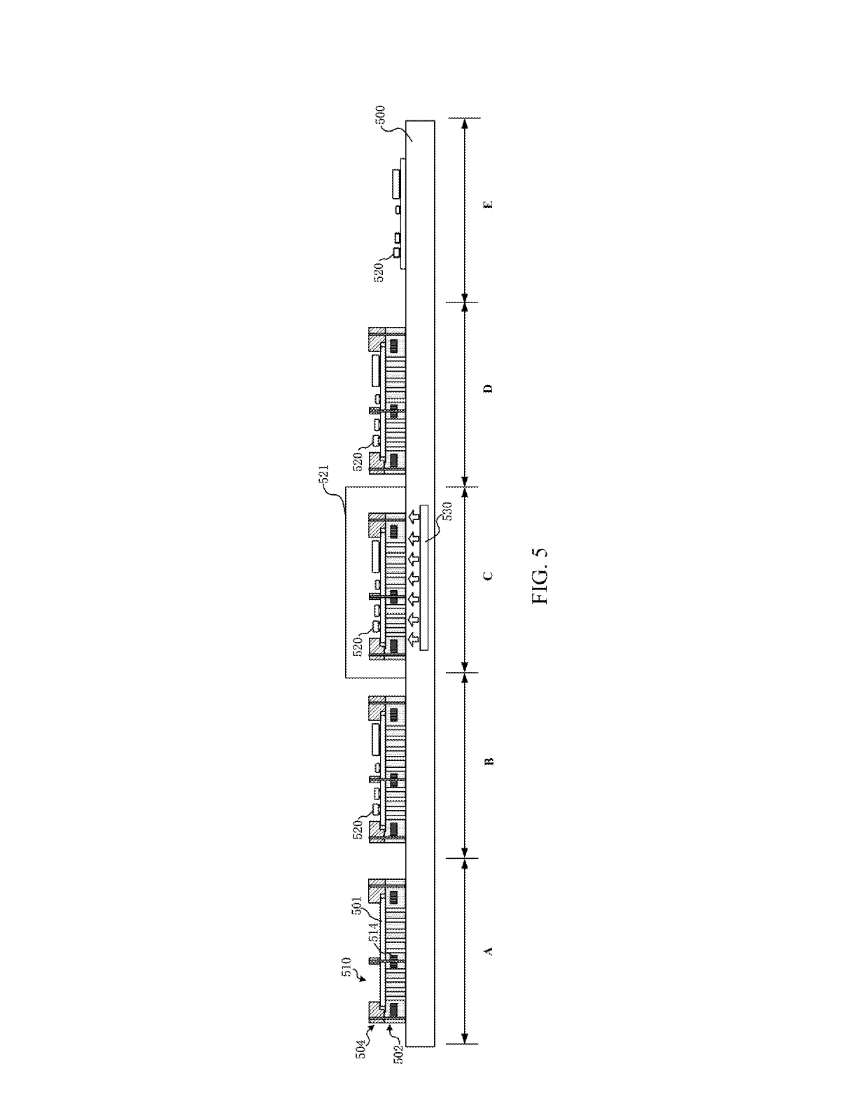

FIG. 5 illustrates an apparatus for forming an electronic module according to a fifth embodiment of the present application. Details of a process of forming the electronic module may be similar to the method for forming the electronic module illustrated in FIGS. 3A to 3D, or FIG. 4.

As shown in FIG. 5, the apparatus may include five sequentially arranged zones, namely, a loading zone A, a mounting zone B, a reflowing zone C, a cooling zone D and an unloading zone E. The apparatus further includes a platform 500, which is used for placing a substrate 501 and a device for holding the substrate 501. The device for holding the substrate 501 includes an upper jig 504 and a lower jig 502 which accommodate the substrate 501 therebetween. Details of the holding device may be similar to the holding device illustrated in FIGS. 1A to 1D. Furthermore, the platform 500 may be in the form of an integrated piece across the loading zone A to the unloading zone E. In some embodiments, a main chamber may be provided to include all of the five zones or even more additional zones as desired, which may prevent contaminants from entering into the apparatus, thereby protecting the substrate 501 and structures thereon during the formation process of the electronic module.

In the embodiment shown in FIG. 5, the lower jig 502, the upper jig 504 and the substrate 501 accommodated between them may be transferred from the loading zone A to the unloading zone E, thereby completing the formation process of the electronic module. In some embodiments, a conveyor may be arranged on the platform 500 and extend from the loading zone A to the unloading zone E. During the fabrication process, the conveyor is used for transporting the substrate 501 from the loading zone A through the mounting zone B, the reflowing zone C and the cooling zone D, and finally to the unloading zone E. The conveyor may include a belt or a carrier on a rail to transport the substrate 501, the lower jig 502 and the upper jig 504 with a controlled speed. It can also be appreciated that the apparatus may not include a conveyor and the substrate 501 may be transported by a manual operation.

To be more specific, in the loading zone A, the substrate 501 is placed between the lower jig 502 and the upper jig 504. More details of this step may be similar to those illustrated in FIG. 3A, and will not be detailed again. In some embodiments, the lower jig 502 further includes a plurality of passages extending through a jig base of the lower jig 502 and fluidly coupled to a vacuum source to apply a vacuum pressure to the substrate 501. Accordingly, the platform 500 may include channels or pipes therewithin, so as to connect the passages of the lower jig 502 to the vacuum source when the device holding the substrate 501 is transported from the loading zone A to the subsequent zones.

Next, the lower jig 502 and the upper jig 504 which hold the substrate 501 are transferred to the mounting zone B. In the mounting zone B, at least one electronic component 520, with a solder paste attached on its bottom surface, passes through the at least one of the plurality of openings 510, respectively. In this way, each of the at least one electronic component 520 is mounted on the substrate 501 via the solder paste. In some embodiments, the solder paste may first be printed or otherwise dispensed to the substrate 501, and the at least one electronic component 520 is mounted on the substrate 501 via the solder paste. In some embodiments, the solder paste may include a metal solder material and a flux material. The details of the mounting step may be similar to those illustrated in FIG. 3B, and will not be detailed again.

Next, the lower jig 502, the upper jig 504 and the substrate 501 are transferred to the reflowing zone C. In the reflowing zone C, a laser source 530 is disposed below the lower jig 502 for emitting laser radiation to reflow the solder paste. A reflowing chamber 521 is arranged on the platform 500 of the reflowing zone C for accommodating the substrate 501, the lower jig 502 and the upper jig 504 during the reflowing process of the solder paste. In some other embodiments, the platform 500 may extend through the reflowing chamber 521. When the substrate 501 is accommodated within the reflowing chamber 521, the laser source 530 is turned on, and the laser radiation is emitted from the laser source 530. In some embodiments, the laser source 530 may be disposed below a top surface of the platform 500 within the reflowing zone C. It can also be appreciated that the laser source 530 may alternatively be disposed below the platform 500. The platform 500 may include a recess or an opening above the laser source 530 such that the laser radiation can get access to the lower jig 502. Since the lower jig 502 is transparent to the laser radiation, the laser radiation may pass through the jig base and reach the substrate 501 and the solder paste. In this way, a sufficient amount of laser radiation energy may then be transferred to the substrate 501 and the solder paste, such that the solder paste can be heated and reflowed to form solder bumps. In this way, the electronic module is formed. During the reflowing process, the grid pattern is in contact with the substrate 501 due to the magnetic attraction by the magnets 514 within the lower jig 502, and thus the substrate 501 can be pressed against the lower jig 502. In addition, a portion of the substrate 501 may also be attracted to the lower jig 502 due to a vacuum attraction force caused by the vacuum pressure applied through the passages of the lower jig 502. More details of the reflowing step of the solder paste may be similar to those illustrated in FIG. 3C, and will not be detailed again.

In some other embodiments, the reflowing zone C further includes a heating block disposed on the platform 500. The heating block may be in direct contact with a bottom surface of the lower jig 502. When the solder paste is heated and reflowed by the laser radiation, the heating block may apply additional heat to the lower jig 502. In addition, the heating block is transparent to the laser radiation, such that the laser radiation can successfully pass through the heating block and the lower jig 502 and reach the substrate 501 and the solder paste. Therefore, the solder paste may be heated through a hybrid heating mechanism. In some yet other embodiments, the heating block may be attached on the lower jig 502 when it is in the loading zone A. The heating block may be turned off when the substrate 501, the lower jig 502 and the upper jig 504 are accommodated within the loading zone A and the mounting zone B, and may be turned on when the substrate 501, the lower jig 502 and the upper jig 504 are accommodated within the reflowing zone C.

In some further embodiments, the heating block may be preheated to a higher temperature than that of the lower jig 502. In this case, the heating block may be attached on the lower jig 502 after the at least one electronic component 520 is mounted on the substrate 501, so as to provide additional thermal energy to the lower jig 502 during the reflowing process. More details of the heating block may be similar to those illustrated in FIG. 2 or FIG. 4, and will not be detailed again.

Next, after electrical connection between the at least one electronic component 520 and the substrate 501 is established through the solder bumps, the laser source 530 may be turned off. The substrate 501, the lower jig 502 and the upper jig 504 are transported to the cooling zone D. In the cooling zone D, the formed electronic module may be cooled down, thereby allowing for sufficient solidification of the formed solder bumps. During the cooling step, the substrate 501 is maintained to be pressed against the lower jig 502 by the upper jig 504, which avoids occurrence of warpage during the cooling step. Next, the flux material may be removed from the electronic module. In some other embodiments, the cooling zone D may be omitted, and the electronic module may be cooled down directly within the reflowing zone C.

Next, the electronic module, the lower jig 502 and the upper jig 504 are transported to the unloading zone E. In the unloading zone E, the upper jig 504 and the lower jig 502 are separated from the substrate 501, and the electronic module can proceed to a testing process or a subsequent fabrication process.

While the device for holding a substrate, a method for forming an electronic module and an apparatus for forming the same of the present application are described in conjunction with corresponding figures, it will be understood by those skilled in the art that modifications and adaptations to the device, the method or the apparatus may be made without departing from the scope of the present invention.

The discussion herein included numerous illustrative figures that showed various portions of a device for holding a substrate, a method for forming an electronic module and an apparatus for forming the same. For illustrative clarity, such figures did not show all aspects of each example device, method or apparatus. Any of the example devices, methods and/or apparatuses provided herein may share any or all characteristics with any or all other devices, methods and/or apparatuses provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A device for holding a substrate, the device comprising:
a lower jig comprising a jig base for placing a substrate, wherein the substrate has at least one electronic component each being mounted thereon via a solder paste, and the jig base is transparent to laser radiation; and
an upper jig operably mounted on the lower jig, and defining together with the lower jig a cavity for accommodating the substrate, wherein the upper jig comprises a frame and a rib inside the frame, and the frame and the rib form a grid pattern defining a plurality of openings for exposing the at least one electronic component from the upper jig, and wherein when the upper jig is mounted on the lower jig to accommodate the substrate inside the cavity and the solder paste is reflowed by the laser radiation, the grid pattern is in contact with the substrate to apply a force to press the substrate against the lower jig.

2. The device of claim 1, wherein the lower jig further comprises a plurality of magnets embedded within the jig base, and the grid pattern of the upper jig is attractable by the plurality of magnets when the upper jig is mounted on the lower jig.

3. The device of claim 2, wherein the grid pattern is at least partially formed of a ferromagnetic material.

4. The device of claim 2, wherein the jig base comprises a plurality of device placement regions and an assembling region, and when the upper jig is mounted on the lower jig, each of the plurality of device placement regions is aligned with one of the openings within the grid pattern, and the assembling region is aligned with the grid pattern.

5. The device of claim 4, wherein the plurality of magnets are embedded within the assembling region.

6. The device of claim 4, wherein the lower jig further comprises a plurality of passages extending through the jig base and fluidly coupled to a vacuum source to apply a vacuum pressure to the substrate via the plurality of passages when the substrate is placed on the lower jig.

7. The device of claim 6, wherein the plurality of passages are distributed within the plurality of device placement regions.

8. The device of claim 1, wherein the upper jig further comprises a skirt portion at a periphery of a bottom surface of the frame such that the cavity is defined between the jig base and the grid pattern to accommodate the substrate, and wherein the skirt portion is in contact with the lower jig when the upper jig is mounted on the lower jig.

9. The device of claim 1, wherein the lower jig further comprises a plurality of fixing pins protruding from its top surface, and the grid pattern further comprises a plurality of through holes for receiving the plurality of fixing pins respectively when the upper jig is mounted on the lower jig to accommodate the substrate.

10. The device of claim 1, wherein the jig base comprises glass or quartz.

11. The device of claim 1, wherein the device further comprises a heating block for placing the lower jig and applying heat to the lower jig, and the heating block is transparent to the laser radiation.

12. A method for forming an electronic module, wherein the method comprises:
placing a substrate between a lower jig and an upper jig, wherein the lower jig comprises a jig base transparent to laser radiation and for holding the substrate, and the upper jig comprises a frame and a rib inside the frame to form a grid pattern which defines a plurality of openings exposing a portion of the substrate;
passing at least one electronic component through at least one of the plurality of openings, respectively, to mount each of the at least one electronic component on the substrate via a solder paste; and
reflowing the solder paste by applying laser radiation to the substrate through the jig base to form the electronic module, wherein the grid pattern is in contact with the substrate to apply a force to press the substrate against the lower jig when the solder paste is being reflowed.

13. The method of claim 12, wherein applying laser radiation to the substrate through the jig base comprises:
applying the laser radiation for a duration ranging between 2 seconds to 5 seconds.

14. The method of claim 12, wherein the lower jig further comprises a plurality of magnets embedded within the jig base, and the grid pattern of the upper jig is attractable by the plurality of magnets when the upper jig is mounted on the lower jig.

15. The method of claim 12, wherein reflowing the solder paste by applying laser radiation to the substrate further comprises:
applying heat to the lower jig by a heating block attached on its bottom surface, wherein the heating block is transparent to the laser radiation.

16. The method of claim 12, wherein the solder paste comprises a metal solder and a flux material, and after applying laser radiation to the substrate through the jig base, the method further comprises:
removing the flux material from the electronic module; and
separating the electronic module from the upper jig and the lower jig.

17. An apparatus for forming an electronic module, the apparatus comprising:
a platform configured for placing a lower jig and an upper jig which define therebetween a cavity for accommodating a substrate having at least one electronic component mounted thereon via a solder paste, wherein the lower jig comprises a jig base which is transparent to laser radiation and for holding the substrate, and the upper jig comprises a frame and a rib inside the frame to form a grid pattern which defines a plurality of openings for exposing the at least one electronic component when the substrate is accommodated in the cavity; and
a laser source configured for applying laser radiation to the substrate through the jig base to reflow the solder paste, wherein the grid pattern is in contact with the substrate to apply a force to press the substrate against the lower jig when the solder paste is being reflowed.

18. The apparatus of claim 17, wherein the platform further comprises:
a loading zone configured for placing the substrate between the lower jig and the upper jig;
a mounting zone configured for disposing the at least one electronic component on the substrate via the solder paste;
a reflowing zone associated with the laser source, wherein the laser source is configured for applying the laser radiation to the substrate when the substrate is in the reflowing zone; and
an unloading zone configured for separating the upper jig and the lower jig from the substrate.
